(19) United States
(12) Patent Application Publication
(10) Pub. No.: US 2025/0051637 A1
(43) Pub. Date: Feb. 13, 2025

(54) SEMICONDUCTOR NANOPARTICLE COMPLEX COMPOSITION, DILUTION COMPOSITION, SEMICONDUCTOR NANOPARTICLE COMPLEX CURED MEMBRANE, SEMICONDUCTOR NANOPARTICLE COMPLEX PATTERNING MEMBRANE, DISPLAY ELEMENT, AND SEMICONDUCTOR NANOPARTICLE COMPLEX DISPERSION LIQUID

(71) Applicant: Shoei Chemical Inc., Tokyo (JP)

(72) Inventors: Makoto KIDO, Tosu-shi (JP); Takafumi MORIYAMA, Tosu-shi (JP); Hirokazu SASAKI, Tosu-shi (JP)

(21) Appl. No.: 18/923,567

(22) Filed: Oct. 22, 2024

Related U.S. Application Data
(63) Continuation of application No. 17/595,920, filed on Nov. 29, 2021.

(30) Foreign Application Priority Data
May 31, 2019 (JP) 2019-103243
May 31, 2019 (JP) 2019-103244
May 31, 2019 (JP) 2019-103245
May 31, 2019 (JP) 2019-103246

(51) Int. Cl. C09K 11/02; B82Y 20/00; B82Y 30/00; B82Y 40/00; C09K 11/54; C09K 11/62; C09K 11/70; H01L 33/00; H01L 33/50

(52) U.S. Cl. CPC C09K 11/02; C09K 11/54; C09K 11/62; C09K 11/70; H01L 33/502; B82Y 20/00; B82Y 30/00; B82Y 40/00; H01L 33/005; H01L 2933/0041; H01L 2933/0091

(57) ABSTRACT

Provided is a semiconductor nanoparticle complex composition and the like in which a semiconductor nanoparticle complex is dispersed at a high concentration and which has high fluorescence quantum yield. A semiconductor nanoparticle complex composition in which a semiconductor nanoparticle complex is dispersed in a dispersion medium, wherein: the semiconductor nanoparticle complex has a semiconductor nanoparticle and a ligand coordinated to the surface of the semiconductor nanoparticle; the ligand includes an organic group; the dispersion medium is a monomer or a prepolymer; the semiconductor nanoparticle complex composition further includes a crosslinking agent; and a mass fraction of the semiconductor nanoparticle in the semiconductor nanoparticle complex composition is 30% by mass or more.

### TECHNICAL FIELD

The present invention relates to a semiconductor nanoparticle complex composition, a dilution composition, a semiconductor nanoparticle complex cured membrane, a semiconductor nanoparticle complex patterning membrane, a display element, and a semiconductor nanoparticle complex dispersion liquid.

This application is a continuation of U.S. patent application Ser. No. 17/595,920, filed Nov. 29, 2021. U.S. patent application Ser. No. 17/595,920 is a national stage application of International Patent Application No. PCT/JP2020021466, filed May 29, 2020. International Patent Application No. PCT/JP2020021466 claims priority based on Japanese Patent Application No. 2019-103243 filed on May 31, 2019, Japanese Patent Application No. 2019-103244 filed on the same day, Japanese Patent Application No. 2019-103245 filed on the same day and Japanese Patent Application No. 2019-103246 filed on the same day, and the contents described in all of the above patent applications are incorporated by reference herein in the entirety.

### BACKGROUND ART

Semiconductor nanoparticles that are so small that a quantum confinement effect is exhibited have a bandgap that depends on the particle diameter. Excitons formed in semiconductor nanoparticles by means of photoexcitation, charge injection, and the like, emit photons with energy corresponding to the band gap by recombination, hence, light emission at a desired wavelength can be obtained by appropriately selecting the composition of the semiconductor nanoparticles and particle diameter thereof.

At the early stage of the research, semiconductor nanoparticles were mainly studied for elements including Cd and Pb, but since Cd and Pb are substances subject to regulation by the Restriction of the Use of Certain Hazardous Substances, in recent years, research on non-Pb-based and non-Cd-based semiconductor nanoparticles has been carried out.

Attempts have been made to use semiconductor nanoparticles in a variety of applications such as display applications, biomarking applications, and solar cell applications. In particular, in display applications, the use of semiconductor nanoparticles formed into a membrane as a wavelength conversion layer has begun.

FIG. 2 shows an outline of a device configuration for converting a wavelength from a light source in a conventional display. As shown in FIG. 2, a blue LED 101 is used as a light source, and first, the blue light is converted into white light. For the conversion from blue light to white light, a QD film 102 formed by dispersing semiconductor nanoparticles in a resin and forming the resin into a film having a thickness of about 100 μm is preferably used. The white light obtained by the wavelength conversion layer such as the QD film 102 is further converted into the red light, green light, and blue light by a color filter (R) 104, a color filter (G) 105, and a color filter (B) 106, respectively. In FIG. 2, the polarizer is omitted.

### CITATION LIST

### Patent Literature

[PTL 1] Japanese Patent Application Publication No. 2002-162501.

### SUMMARY OF INVENTION

### Technical Problem

In recent years, a display of a type that uses a QD pattern as a wavelength conversion layer without using a QD film (deflection plate is not shown), as shown in FIG. 1, has been developed. In the type of display shown in FIG. 1, a QD pattern (7, 8) is used to directly convert blue light to red light or blue light to green light without converting the blue light from the blue LED 1 as a light source into white light. The QD pattern (7, 8) is formed by patterning semiconductor nanoparticles dispersed in a resin, and the thickness is about 5 μm to 10 μm due to the structural limitation of the display. Regarding the blue color, blue light from the blue LED 1 which is a light source is transmitted through a diffusion layer 9 including a diffusing agent.

Also, where the QD pattern (7, 8) does not absorb blue light sufficiently and allows the light to pass through, color mixing will occur. The higher the mass fraction of the semiconductor nanoparticles in the QD pattern (7, 8), the more the absorbance of the pattern can be improved and the color mixing can be prevented.

Patent Literature 1 (Japanese Patent Application Publication No. 2002-162501) discloses a thin-membrane molded product including semiconductor nanoparticles at a high mass fraction. Since the thin-membrane molded product described in Patent Literature 1 does not necessarily require a polymer matrix component, it is possible to form a thin-membrane molded product including semiconductor nanoparticles at a high mass fraction. However, it has become clear that when the thin-membrane molded product described in Patent Literature 1 is used as a wavelength conversion layer for a display or the like, the strength, stability, and solvent resistance of the molded product are insufficient.

When a semiconductor nanoparticle complex is used for a wavelength conversion layer, the semiconductor nanoparticles and the semiconductor nanoparticle complex may be exposed to a high temperature of about 200° C. in the presence of oxygen in the process including a step of forming a film including the semiconductor nanoparticles, a step of baking a photoresist including the semiconductor nanoparticles, a step of removing a solvent and curing a resin after inkjet patterning of semiconductor nanoparticles, and the like. At that time, a ligand having a weak force of binding to the semiconductor nanoparticle is easily detached from the surface of the semiconductor nanoparticle, which causes a decrease in the fluorescence quantum yield of the semiconductor nanoparticle complex and the wavelength conversion layer itself.

Therefore, an object of the present invention is to provide a semiconductor nanoparticle complex composition and the like in which a semiconductor nanoparticle complex is dispersed at a high concentration and which has high fluorescence quantum yield.

### Solution to Problem

The semiconductor nanoparticle complex composition according to the present invention is a semiconductor nanoparticle complex composition in which a semiconductor nanoparticle complex is dispersed in a dispersion medium, wherein
the semiconductor nanoparticle complex has a semiconductor nanoparticle and a ligand coordinated to the surface of the semiconductor nanoparticle;
the ligand includes an organic group;
the dispersion medium is a monomer or a prepolymer;
the semiconductor nanoparticle complex composition further includes a crosslinking agent; and
a mass fraction of the semiconductor nanoparticle in the semiconductor nanoparticle complex composition is 30% by mass or more.

In the present application, the range indicated by preposition “to” includes the numbers indicated at both ends thereof.

### Advantageous Effects of Invention

According to the present invention, it is possible to provide a semiconductor nanoparticle complex composition or the like in which the semiconductor nanoparticle complex is dispersed at a high concentration and which has high fluorescence quantum yield.

### BRIEF DESCRIPTION OF DRAWINGS

FIG. 1 shows an outline of an example of a display in which a semiconductor nanoparticle complex composition according to an embodiment of the present invention is used as a QD pattern.

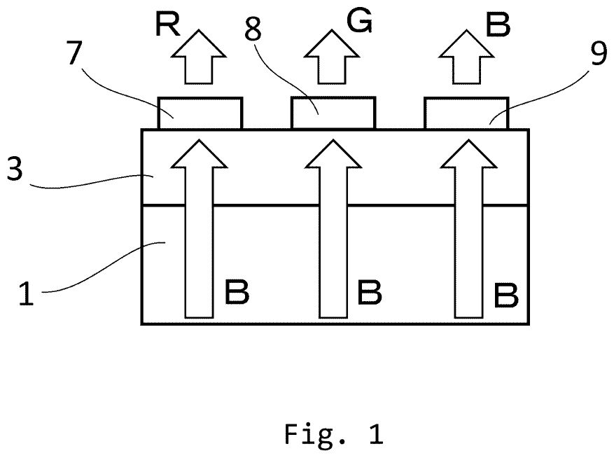

FIG. 2 shows an outline of an example of a display using semiconductor nanoparticles as a QD film.

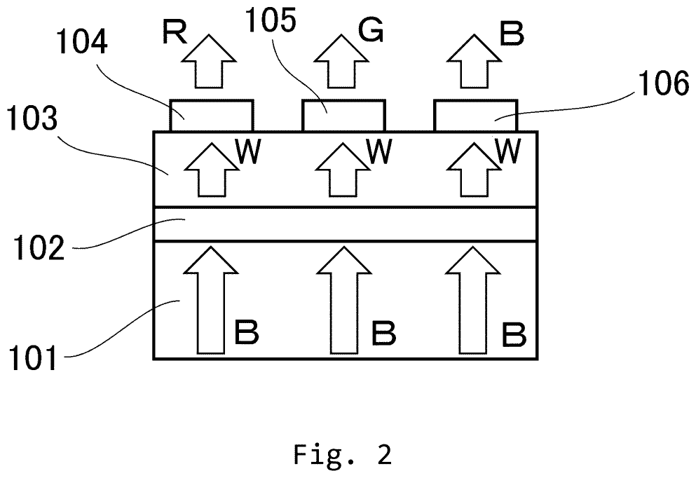

### DESCRIPTION OF EMBODIMENTS

The semiconductor nanoparticle complex composition and the semiconductor nanoparticle complex dispersion liquid of the present invention are obtained by dispersing the semiconductor nanoparticle complex in a dispersion medium. The semiconductor nanoparticle complex composition has a dispersion medium of a monomer or a prepolymer, further includes a crosslinking agent, and has a mass fraction of semiconductor nanoparticles of 30% by mass or more. Further, the dilution composition of the present invention is obtained by diluting the semiconductor nanoparticle complex composition of the present invention with an organic solvent.

The semiconductor nanoparticle complex cured membrane and the semiconductor nanoparticle complex patterning membrane of the present invention are formed by curing or patterning the semiconductor nanoparticle complex composition or the dilution composition of the present invention. The display element of the present invention includes the semiconductor nanoparticle complex patterning membrane of the present invention.

### (Semiconductor Nanoparticle Complex)

The present invention relates to a semiconductor nanoparticle complex composed of semiconductor nanoparticles and a ligand coordinated to the semiconductor nanoparticle, a semiconductor nanoparticle complex composition in which the semiconductor nanoparticle complex is dispersed, and the like. The semiconductor nanoparticle complex dispersed in the semiconductor nanoparticle complex composition of the present invention has high luminescence characteristics, and the semiconductor nanoparticle complex can be contained at a high mass fraction in the semiconductor nanoparticle complex dispersion liquid, semiconductor nanoparticle complex composition, dilution composition, semiconductor nanoparticle complex cured membrane, and semiconductor nanoparticle complex patterning membrane. Further, the obtained semiconductor nanoparticle complex cured membrane and the semiconductor nanoparticle complex patterning membrane have high fluorescence quantum yield.

In the present invention, the semiconductor nanoparticle complex is a semiconductor nanoparticle complex having light emission characteristics. The semiconductor nanoparticle complex contained in the semiconductor nanoparticle complex composition and the semiconductor nanoparticle complex dispersion liquid of the present invention is a particle that absorbs light of 340 nm to 480 nm and emits light having an emission peak wavelength of 400 nm to 750 nm.

The full width at half maximum (FWHM) of the emission spectrum of the semiconductor nanoparticle complex is preferably 38 nm or less, and more preferably 35 nm or less. Where the full width at half maximum of the emission spectrum is within the above range, color mixing can be reduced when the semiconductor nanoparticle complex is applied to a display or the like.

The fluorescence quantum yield (QY) of the semiconductor nanoparticle complex is preferably 80% or more, and more preferably 85% or more. When the fluorescence quantum yield of the semiconductor nanoparticle complex is 80% or more, color conversion can be performed more efficiently. In the present invention, the fluorescence quantum yield of the semiconductor nanoparticle complex can be measured using a quantum yield measurement system.

### —Semiconductor Nanoparticle—

A semiconductor nanoparticle constituting the semiconductor nanoparticle complex is not particularly limited as long as the above-mentioned fluorescence quantum yield and light emission characteristics such as full width at half maximum are satisfied, and may be a particle made of one type of semiconductor or a particle composed of two or more different semiconductors. In the case of particles composed of two or more different types of semiconductors, a core-shell structure may be composed of these semiconductors. For example, the particle may be of a core-shell type having a core including a Group III element and a Group V element and a shell including a Group II element and a Group VI element covering at least a part of the core. Here, the shell may have a plurality of shells having different compositions, or may have one or more gradient-type shells in which the ratio of elements constituting the shell changes in the shell.

Specific examples of Group III elements include In, Al and Ga.

Specific examples of Group V elements include P, N and As.

The composition for forming the core is not particularly limited, but InP is preferable from the viewpoint of light emission characteristics.

The Group II element is not particularly limited, and examples thereof include Zn and Mg.

Examples of Group VI elements include S, Se, Te and O.

The composition for forming the shell is not particularly limited, but from the viewpoint of the quantum confinement effect, ZnS, ZnSe, ZnSeS, ZnTeS, ZnTeSe, and the like are preferable. In particular, when a Zn element is present on the surface of the semiconductor nanoparticle, the effect of the present invention can be exerted to a greater extent.

When the nanoparticle has a plurality of shells, it is sufficient that at least one shell having the above-mentioned composition be included. Further, in the case of a gradient type shell in which the ratio of elements constituting the shell changes in the shell, the shell does not necessarily have to have the composition according to the composition notation.

Here, in the present invention, whether the shell covers at least a part of the core and the element distribution inside the shell can be confirmed by composition analysis by, for example, energy dispersive X-ray spectroscopy (TEM-EDX) using a transmission electron microscope.

The average particle diameter of the semiconductor nanoparticle complex is preferably 10 nm or less. Further, the semiconductor nanoparticle complex is more preferably 7 nm or less.

In the present invention, the average particle diameter of semiconductor nanoparticles can be measured by calculating the particle diameter of 10 or more particles by an area equivalent diameter (Heywood diameter) in a particle image observed using a transmission electron microscope (TEM). From the viewpoint of light emission characteristics, a narrow particle size distribution is preferable, and a coefficient of variation of the particle diameter is preferably 15% or less. Here, the coefficient of variation is defined as “coefficient of variation=(standard deviation of particle diameter)/(average particle diameter)”. The coefficient of variation of 15% or less indicates that semiconductor nanoparticles having a narrower particle diameter distribution are obtained.

Disclosed hereinbelow is an example of a method for producing semiconductor nanoparticles.

A core of a semiconductor nanoparticle can be formed by heating a precursor mixture obtained by mixing a Group III precursor, a Group V precursor, and, if necessary, an additive in a solvent.

Examples of the solvent include, but are not limited to, 1-octadecene, hexadecane, squalene, oleylamine, trioctylphosphine, and trioctylphosphine oxide.

Examples of Group III precursors include, but are not limited to, acetates, carboxylates, halides, and the like containing the Group III elements.

Examples of Group V precursors include, but are not limited to, organic compounds and gases containing the Group V elements. Where the precursor is a gas, a core can be formed by reacting while injecting a gas into a precursor mixture including components other than the gas.

The semiconductor nanoparticles may include one or two or more elements other than Group III and Group V as long as the effects of the present invention are not impaired. In this case, the precursor(s) of the element(s) may be added at the time of core formation.

Examples of the additive include, but are not limited to, carboxylic acids, amines, thiols, phosphines, phosphine oxides, phosphinic acids, and phosphonic acids as dispersants. The dispersant can also serve as a solvent.

After forming the core of the semiconductor nanoparticles, the emission characteristics of the semiconductor nanoparticles can be improved by adding a halide as needed.

In one embodiment, an In precursor and, if necessary, a metal precursor solution obtained by adding a dispersant to a solvent are mixed under vacuum and heated once at 100° C. to 300° C. for 6 h to 24 h, followed by the addition of a P precursor, heating at 200° C. to 400° C. for 3 min to 60 min, and then cooling. Further, by adding a halogen precursor and heat-treating at 25° C. to 300° C., preferably 100° C. to 300° C., and more preferably 150° C. to 280° C., a core particle dispersion liquid including core particles can be obtained.

By adding the shell-forming precursor to the core particle dispersion synthesized as described above, the semiconductor nanoparticles have a core-shell structure, and the fluorescence quantum yield (QY) and stability can be improved.

The elements that constitute the shell are thought to have a structure such as an alloy, heterostructure, or amorphous structure on the surface of the core particles, but it is also conceivable that some of them have moved to the inside of the core particles due to diffusion.

The added shell-forming element is mainly present near the surface of the core particle and has a role of protecting the semiconductor nanoparticle from external factors. In the core-shell structure of the semiconductor nanoparticles, it is preferable that the shell covers at least a part of the core, and more preferably the entire surface of the core particle is uniformly covered.

In one embodiment, a Zn precursor and a Se precursor are added to the core particle dispersion liquid described above, then heating is performed at 150° C. to 300° C., preferably 180° C. to 250° C., and then the Zn precursor and the S precursor are added and heating is performed at 200° C. to 400° C., preferably 250° C. to 350° C. As a result, core-shell type semiconductor nanoparticles can be obtained.

Here, although not particularly limited, examples of suitable Zn precursors include carboxylates such as zinc acetate, zinc propionate and zinc myristate, halides such as zinc chloride and zinc bromide, and organic salts such as diethyl zinc.

Examples of suitable Se precursors include phosphine selenides such as tributylphosphine selenide, trioctylphosphine selenide and tris(trimethylsilyl)phosphine selenide, selenols such as benzeneselenol and selenocysteine, and selenium/octadecene solutions.

Examples of suitable S precursors include phosphine sulfides such as tributylphosphine sulfide, trioctylphosphine sulfide and tris(trimethylsilyl)phosphine sulfide, thiols such as octanethiol, dodecanethiol and octadecanethiol, and sulfur/octadecene solutions.

The precursors of the shell may be mixed in advance and added once or in multiple times, or each may be added separately once or in multiple times. When the shell precursors are added in multiple times, heating by changing the temperature may be performed after each shell precursor is added.

In the present invention, a method for producing semiconductor nanoparticles is not particularly limited, and in addition to the methods shown above, conventional methods such as a hot injection method, a uniform solvent method, a reverse micelle method, and a CVD method can be used, or any other method may be adopted.

### —Ligand—

In the present invention, in a semiconductor nanoparticle complex, ligands are coordinated to the surface of the semiconductor nanoparticle. The coordination mentioned herein means that the ligand chemically affects the surface of the semiconductor nanoparticle. The ligand may be bonded to the surface of the semiconductor nanoparticle by coordination bonding or in any other bonding mode (for example, by covalent bond, ionic bond, hydrogen bond, and the like), or when the ligand is present on at least a portion of the surface of the semiconductor nanoparticle, the ligand does not necessarily have to form a bond.

A semiconductor nanoparticle complex that can be contained at a high mass fraction in a semiconductor nanoparticle complex composition, a semiconductor nanoparticle complex cured membrane, and during patterning preferably satisfies the following conditions.

The mass ratio of the ligand to the semiconductor nanoparticle is preferably 0.05 to 0.50, and more preferably 0.10 to 0.40, when the semiconductor nanoparticle is taken as 1. When the mass ratio of the ligand to the semiconductor nanoparticle (ligand/semiconductor nanoparticle) is 0.50 or less, it is possible to suppress an increase in the size and volume of the semiconductor nanoparticle complex, and the semiconductor nanoparticle complex can be contained at a high mass fraction in the semiconductor nanoparticle complex composition and the semiconductor nanoparticle complex cured membrane. Further, when the mass ratio (ligand/semiconductor nanoparticle) is 0.05 or more, the ligand can sufficiently cover the semiconductor nanoparticle, and a decrease in the emission characteristics of the semiconductor nanoparticles and a decrease in dispersibility in the cured membrane or dispersion medium can be suppressed.

The fluorescence quantum yield of the semiconductor nanoparticle complex composition and the semiconductor nanoparticle complex cured membrane is preferably 60% or more, and more preferably 70% or more.

The ligand is an organic ligand including an organic group. Further, the ligand is preferably composed of a coordinating group that coordinates to the semiconductor nanoparticle and an organic group.

The organic group is preferably a monovalent hydrocarbon group which may have a substituent or a heteroatom, and more preferably an organic group in which a substituent including a heteroatom is bonded to a vinyl group. By adopting this structure, the semiconductor nanoparticle complex can be dispersed in the below-described cured membrane at a high mass fraction while maintaining a high quantum yield. The organic group is not particularly limited, and can include an alkyl group, an alkenyl group, an alkynyl group, a vinylene group, a vinylidene group, an ether group, an ester group, a carbonyl group, an amide group, a sulfide group, and an organic group formed by combining these. Further, the organic group can include a phenyl group, a hydroxyl group, an alkoxy group, an amino group, a carboxyl group, a mercapto group, a chloro group, a bromo group, a vinyl group, an acrylic group, a methacryl group, or the like as a substituent. The organic group preferably has one or more groups selected from an ether group, an ester group, and an amide group. Such a structure enables dispersion in an organic dispersion medium having an SP value (solubility parameter) of 8.5 to 15.0. Further, it is more preferable that the organic group has a vinyl group and/or a vinylene group. By adopting this structure, the semiconductor nanoparticle complex and the curable composition can be chemically bonded, and the strength of the membrane and the stability of the semiconductor nanoparticles in the membrane are improved. The substituent including a vinyl group is not particularly limited, and examples thereof include an acrylic group, a methacrylic group, and the like.

The coordinating group is preferably a mercapto group or a carboxyl group, and particularly preferably a mercapto group, because of the strength of coordination to the semiconductor nanoparticle. The number of mercapto groups is preferably one or more. By coordinating the coordinating group of the ligand to the surface of the semiconductor nanoparticle, it is possible to prevent a decrease in the fluorescence quantum yield of the semiconductor nanoparticle. Further, when the semiconductor nanoparticle complex having the ligand is used for the wavelength conversion layer, the ligand is strongly coordinated to the semiconductor nanoparticle even when exposed to a high processing temperature. Therefore, it is possible to prevent a decrease in the fluorescence quantum yield of the wavelength conversion layer.

Multiple types of ligands may be used in combination.

As the first embodiment of the semiconductor nanoparticle complex, the molecular weight of the ligand is preferably 50 or more and 600 or less, and more preferably 50 or more and 450 or less. Where a plurality of types of ligands is used in combination, the molecular weight of each ligand is preferably 50 or more and 600 or less, and more preferably 50 or more and 450 or less.

By using a ligand having a molecular weight of 600 or less, it is possible to suppress an increase in the size and volume of the semiconductor nanoparticle complex and easily increase the mass fraction of the semiconductor nanoparticles in the cured membrane. Meanwhile, by using a ligand having a molecular weight of 50 or more, the surface of the semiconductor nanoparticles can be sufficiently covered with the ligand, so that deterioration of light emission characteristics of the semiconductor nanoparticle complex can be suppressed, and dispersibility in a cured membrane or a dispersion medium can be improved.

Further, as another embodiment of the semiconductor nanoparticle complex, the ligand preferably has two or more coordinating groups per molecule. When the number of coordinating groups of the ligand is two or more per molecule of the ligand, one molecule of the ligand can coordinate to a plurality of locations on the surface of the semiconductor nanoparticle, so that an increase in size and volume of the semiconductor nanoparticle complex can be suppressed, and dispersibility in a dispersion medium or a cured membrane can be improved.

The mercapto group is preferable as the coordinating group of the ligand. The mercapto group of the ligand strongly coordinates to the shell of the semiconductor nanoparticle, fills the defective portion of the semiconductor nanoparticles, and contributes to prevent deterioration of the light emission characteristics of the semiconductor nanoparticle complex. In particular, when Zn is present on the surface of the semiconductor nanoparticle, the above-mentioned effect can be exerted to a greater extent due to the strength of the bonding force between the mercapto group and Zn.

### (Method for Producing Semiconductor Nanoparticle Complex)

The following is an example of a method for producing a semiconductor nanoparticle complex.

A method for coordinating a ligand to a semiconductor nanoparticle is not limited, and a ligand exchange method using the coordinating force of the ligand can be used. Specifically, semiconductor nanoparticles in which the organic compound used in the process of producing the semiconductor nanoparticles described above is coordinated to the surface of the semiconductor nanoparticles are brought into contact with the target ligand in a liquid phase, thereby making it possible to obtain a semiconductor nanoparticle complex in which the target ligand is coordinated to the surface of the semiconductor nanoparticle. In this case, a liquid-phase reaction using a solvent as described hereinbelow is usually carried out, but when the ligand to be used is a liquid under the reaction conditions, a reaction mode is possible in which the ligand itself is used as a solvent and no other solvent is added.

Further, where the below-described purification step and redispersion step are performed before the ligand exchange, the ligand exchange can be easily performed.

In one embodiment, the desired semiconductor nanoparticle complex can be obtained by purifying and then redispersing the semiconductor nanoparticle-containing dispersion liquid after the semiconductor nanoparticles are produced, then adding a solvent including the target ligand, and stirring at a temperature of 50° C. to 200° C. for 1 min to 120 min in a nitrogen atmosphere.

The semiconductor nanoparticles and semiconductor nanoparticle complex can be purified in the following manner. In one embodiment, the semiconductor nanoparticle complex can be precipitated from the dispersion liquid by adding a polarity-changing solvent such as acetone. The precipitated semiconductor nanoparticle complex can be collected by filtration or centrifugation, while supernatant containing unreacted starting materials and other impurities may be discarded or reused. The precipitated semiconductor nanoparticle complex can then be washed with additional dispersion medium and dispersed again. This purification process can be repeated, for example, 2 to 4 times, or until the desired purity is achieved.

In the present invention, the method for purifying the semiconductor nanoparticle complex is not particularly limited, and in addition to the methods shown above, for example, flocculation, liquid-liquid extraction, distillation, electrodeposition, size-selection chromatography and/or ultrafiltration, and the like may be used. Any method can be used alone or in combination.

Further, the optical characteristics of the semiconductor nanoparticles can be measured using a quantum yield measurement system (for example, manufactured by Otsuka Electronics Co., Ltd., QE-2100). The obtained semiconductor nanoparticles are dispersed in a dispersion medium, excitation light is used to obtain an emission spectrum, and the fluorescence quantum yield (QY) and full width at half maximum (FWHM) are calculated from the emission spectrum after re-excitation correction in which a re-excitation fluorescence emission spectrum corresponding to fluorescence emission by reexcitation is excluded from the emission spectrum obtained herein. Examples of the dispersion medium used for the measurement include normal hexane, toluene, acetone, PGMEA and octadecene.

In the present invention, the state in which the semiconductor nanoparticle complex is dispersed in the dispersion medium represents a state in which the semiconductor nanoparticle complex does not precipitate or a state in which the semiconductor nanoparticle complex does not remain creating visible turbidity (cloudiness) when the semiconductor nanoparticle complex and the dispersion medium are mixed. A liquid obtained by dispersing the semiconductor nanoparticle complex in a dispersion medium is referred to as a semiconductor nanoparticle complex dispersion liquid.

Where the semiconductor nanoparticle complex composition of the present invention and the semiconductor nanoparticle complex contained in the semiconductor nanoparticle complex dispersion liquid have the above-mentioned configuration, a semiconductor nanoparticle complex dispersion liquid is formed by dispersing in a dispersion medium having an SP value (dissolution parameter) of 8.5 to 15.0 as a dispersion medium.

Examples of the dispersion medium include, but are not particularly limited to, alcohols such as methanol, ethanol, isopropyl alcohol, normal propyl alcohol, and the like, ketones such as acetone, methyl ethyl ketone, methyl isobutyl ketone, cyclopentanone, cyclohexanone, and the like, esters such as methyl acetate, ethyl acetate, isopropyl acetate, normal propyl acetate, normal butyl acetate, ethyl lactate, and the like, ethers such as diethyl ether, dipropyl ether, dibutyl ether, tetrahydrofuran, and the like, glycol ethers such as ethylene glycol monomethyl ether, ethylene glycol monoethyl ether, diethylene glycol monomethyl ether, ethylene glycol diethyl ether, diethylene glycol dimethyl ether, propylene glycol monomethyl ether (PGME), propylene glycol monoethyl ether, propylene glycol monopropyl ether, propylene glycol monobutyl ether, propylene glycol dimethyl ether, dipropylene glycol dimethyl ether, propylene glycol diethyl ether, dipropylene glycol diethyl ether, and the like, and glycol ether esters such as ethylene glycol acetate, ethylene glycol monoethyl ether acetate, diethylene glycol monoethyl ether acetate, diethylene glycol monobutyl ether acetate, propylene glycol monomethyl ether acetate (PGMEA), dipropylene glycol monoethyl ether acetate, and the like. The semiconductor nanoparticle complex can be dispersed in any one or more dispersion media selected from the above dispersion media. Further, as described in the above examples, it is also possible to select dispersion media having polarity such as alcohols, ketones, esters, glycol ethers, glycol ether esters, and the like.

When the semiconductor nanoparticle complex dispersed in such dispersion media is adopted for dispersion in the below-described cured membrane or resin, the dispersion can be used while maintaining the dispersibility of the semiconductor nanoparticle complex. Among the aforementioned dispersion media, glycol ethers and glycol ether esters are preferable from the viewpoint of solubility in a wide range of resins and membrane uniformity at the time of coating. In particular, in the field of photoresists, PGMEA and PGME are generally used as diluting solvents, and where the semiconductor nanoparticles can be dispersed in PGMEA and PGME, the semiconductor nanoparticles can be widely applied to the photoresist field.

The SP value here is the Hildebrand solubility parameter, which is a value calculated from the Hansen solubility parameter. The Hansen solubility parameter is described in the handbook, for example, “Hansen Solubility Parameters: A User's Handbook”, 2nd Edition, C. M. Hanson (2007), and can be determined using a Practice (HSPiP) program (2nd edition) provided by Hanson and Abbot et al.

When the concentration of the inorganic component of the semiconductor nanoparticle complex in the semiconductor nanoparticle complex dispersion liquid is 1 mg/mL, that is, when the content of the inorganic component of the semiconductor nanoparticle complex per 1 mL of the dispersion medium of the semiconductor nanoparticle complex dispersion liquid is 1 mg, the absorbance of the semiconductor nanoparticle complex dispersion liquid may be 0.6 or more, and more preferably 0.7 or more at an optical path length of 1 cm with respect to light having a wavelength of 450 nm. When the absorbance of the dispersion liquid is 0.6 or more at an optical path length of 1 cm, it is possible to absorb more light with a small amount of liquid in applications to devices or the like.

The semiconductor nanoparticle complex described above is suitable as a semiconductor nanoparticle complex to be included in the semiconductor nanoparticle complex composition, dilution composition, semiconductor nanoparticle complex cured membrane, semiconductor nanoparticle complex patterning membrane, display element, and semiconductor nanoparticle complex dispersion liquid of the present invention.

### (Semiconductor Nanoparticle Complex Composition)

In the present invention, a monomer or a prepolymer can be selected as the dispersion medium of the semiconductor nanoparticle complex dispersion liquid. Further, by adding a crosslinking agent, the semiconductor nanoparticle complex contained in the semiconductor nanoparticle complex composition of the present invention can form a semiconductor nanoparticle complex composition together with the monomer or prepolymer and the crosslinking agent.

The monomer is not particularly limited, but a (meth)acrylic monomer that enables selection of a wide range of applications for the semiconductor nanoparticles is preferable. The (meth)acrylic monomer can be selected according to the application of the semiconductor nanoparticle complex dispersion liquid from the group consisting of isobornyl acrylate (IBOA), methyl (meth)acrylate, ethyl (meth)acrylate, propyl (meth)acrylate, butyl (meth)acrylate, isobutyl (meth)acrylate, isoamyl (meth)acrylate, octyl (meth)acrylate, 2-ethylhexyl (meth)acrylate, dodecyl (meth)acrylate, isodecyl (meth)acrylate, lauryl (meth)acrylate, stearyl (meth)acrylate, cyclohexyl (meth)acrylate, isobornyl (meth)acrylate, 3,5,5-trimethylcyclohexanol (meth)acrylate, dicyclopentanyl (meth)acrylate, dicyclopentenyl (meth)acrylate, methoxyethyl (meth)acrylate, ethyl carbitol (meth)acrylate, methoxytriethylene glycol acrylate, 2-ethylhexyl diglycol acrylate, methoxypolyethylene glycol acrylate, methoxydipropylene glycol acrylate, phenoxyethyl (meth)acrylate, 2-phenoxydiethylene glycol (meth)acrylate, 2-phenoxypolyethylene glycol (meth)acrylate (n≈2), tetrahydrofurfuryl (meth)acrylate, 2-hydroxyethyl acrylate, 2-hydroxypropyl (meth)acrylate, 4-hydroxybutyl (meth)acrylate, 2-hydroxybutyl (meth)acrylate, dicyclopentanyloxyl ethyl (meth)acrylate, isobornyloxyl ethyl (meth)acrylate, adamantyl (meth)acrylate, dimethyladamantyl (meth)acrylate, dicyclopentenyloxyethyl (meth)acrylate, benzyl (meth)acrylate, ω-carboxy-polycaprolactone (n≈2) monoacrylate, 2-hydroxy-3-phenoxypropyl acrylate, 2-hydroxy-3-phenoxyethyl (meth)acrylate, (2-methyl-2-ethyl-1,3-dioxolan-4-yl) methyl (meth)acrylate, (3-ethyloxetane-3-yl) methyl (meth)acrylate, o-phenylphenolethoxy (meth)acrylate, dimethylamino (meth)acrylate, diethylamino (meth)acrylate, 2-(meth)acryloyloxyethylphthalic acid, 2-(meth)acryloyloxyethylhexahydrophthalic acid, glycidyl (meth)acrylate, 2-(meth)acryloyloxyethylphosphoric acid, acryloylmorpholine, dimethylacrylamide, dimethylaminopropylacrylamide, iropropylacrylamide, diethylacrylamide, hydroxyethylacrylamide, and N-acryloyloxyethyl hexahydrophthalimide. These can be used alone or in combination of two or more. The prepolymer is not particularly limited, and examples thereof include a (meth)acrylic resin prepolymer, a silicone resin prepolymer, an epoxy resin prepolymer, a maleic acid resin prepolymer, a butyral resin prepolymer, a polyester resin prepolymer, a melamine resin prepolymer, a phenol resin prepolymer, a polyurethane resin prepolymer, and the like.

Depending on the type of monomer in the semiconductor nanoparticle complex composition, the crosslinking agent may be selected from a polyfunctional (meth)acrylate, a polyfunctional silane compound, a polyfunctional amine, a polyfunctional carboxylic acid, a polyfunctional thiol, a polyfunctional alcohol, and a polyfunctional isocyanate.

Further, the semiconductor nanoparticle complex composition can further include various organic solvents that do not affect curing, such as aliphatic hydrocarbons such as pentane, hexane, cyclohexane, isohexane, heptane, octane, and petroleum ether, alcohols, ketones, esters, glycol ethers and glycol ether esters, aromatic hydrocarbons such as benzene, toluene, xylene and mineral spirits, and alkyl halides such as dichloromethane and chloroform. When the semiconductor nanoparticle complex composition includes an organic solvent, the content of the organic solvent may be such that the mass fraction of the semiconductor nanoparticles in the semiconductor nanoparticle complex composition is 30% or more.

Further, the semiconductor nanoparticle complex composition may include an appropriate initiator, scattering agent, catalyst, binder, surfactant, adhesion promoter, antioxidant, UV absorber, anti-aggregation agent, a dispersant, and the like depending on the type of monomer in the semiconductor nanoparticle complex composition.

Further, in order to improve the optical characteristics of the semiconductor nanoparticle complex composition or the semiconductor nanoparticle complex cured membrane described hereinbelow, the semiconductor nanoparticle complex composition may include a scattering agent. The scattering agent is a metal oxide such as titanium oxide or zinc oxide, and the particle diameter thereof is preferably 100 nm to 500 nm. From the viewpoint of the effect of scattering, the particle diameter of the scattering agent is more preferably 200 nm to 400 nm. By including the scattering agent, the absorbance is improved by a factor of about twice. The amount of the scattering agent is preferably 2% by mass to 30% by mass, and more preferably 5% by mass to 20% by mass from the viewpoint of maintaining the patterning property of the composition.

With the configuration of the semiconductor nanoparticle complex of the present invention, the mass fraction of the semiconductor nanoparticles in the semiconductor nanoparticle complex composition can be set to 30% by mass or more. By setting the mass fraction of the semiconductor nanoparticles in the semiconductor nanoparticle complex composition to 30% by mass to 95% by mass, the semiconductor nanoparticle complex and the semiconductor nanoparticles can be dispersed in the below-described cured membrane at a high mass fraction.

When the semiconductor nanoparticle complex composition of the present invention is formed into a membrane having a thickness of 10 μm, the absorbance of the membrane with respect to light having a wavelength of 450 nm from the normal direction is preferably 1.0 or more, more preferably 1.3 or more. And even more preferably 1.5 or more. As a result, the light from the backlight can be efficiently absorbed, so that the thickness of the cured membrane described hereinbelow can be reduced, and the device using the membrane can be miniaturized.

### (Dilution Composition)

The dilution composition of the present invention is obtained by diluting the above-mentioned semiconductor nanoparticle complex composition of the present invention with an organic solvent.

The organic solvent for diluting the semiconductor nanoparticle complex composition is not particularly limited, and examples thereof include aliphatic hydrocarbons such as pentane, hexane, cyclohexane, isohexane, heptane, octane, and petroleum ether, alcohols, ketones, esters, glycol ethers, glycol ether esters, aromatic hydrocarbons such as benzene, toluene, xylene and mineral spirit, and alkyl halides such as dichloromethane and chloroform. Among these, glycol ethers and glycol ether esters are preferable from the viewpoint of solubility in a wide range of resins and membrane uniformity at the time of coating.

Where the organic solvent contained in the dilution composition of the present invention is removed by drying or the like, a semiconductor nanoparticle complex composition having a mass fraction of semiconductor nanoparticles of 30% or more can be obtained.

### (Semiconductor Nanoparticle Complex Cured Membrane)

In the present invention, the semiconductor nanoparticle complex cured membrane is a membrane that includes a semiconductor nanoparticle complex and has been cured. The semiconductor nanoparticle complex cured membrane can be obtained by curing the above-mentioned semiconductor nanoparticle complex composition or diluted composition into a membrane.

The semiconductor nanoparticle complex cured membrane includes semiconductor nanoparticles, ligands coordinated on the surface of the semiconductor nanoparticles, a polymer matrix, and a crosslinking agent.

The polymer matrix is not particularly limited, and examples thereof include (meth)acrylic resins, silicone resins, epoxy resins, maleic acid resins, butyral resins, polyester resins, melamine resins, phenol resins, polyurethane resins, and the like. A semiconductor nanoparticle complex cured membrane may be obtained by curing the semiconductor nanoparticle complex composition described above.

A method for curing the membrane is not particularly limited, and the membrane can be cured by a curing method suitable for the composition constituting the membrane, such as heat treatment and ultraviolet treatment.

The semiconductor nanoparticle and the ligand coordinated to the surface of the semiconductor nanoparticle, which are included in the semiconductor nanoparticle complex cured membrane, preferably constitute the above-described semiconductor nanoparticle complex. By configuring the semiconductor nanoparticle complex contained in the semiconductor nanoparticle complex cured membrane of the present invention as described above, the semiconductor nanoparticle complex can be dispersed in the cured membrane at a higher mass fraction. The mass fraction of the semiconductor nanoparticles in the semiconductor nanoparticle complex cured membrane may be 30% by mass or more, and more preferably 40% by mass or more. However, where the mass fraction is 70% by mass or more, the amount of the composition constituting the membrane is reduced, and it becomes difficult to cure and form the membrane.

As a result of including the semiconductor nanoparticle complex described above in the semiconductor nanoparticle complex cured membrane of the present invention, the semiconductor nanoparticle complex cured membrane of the present invention has a very high absorbance of light having a wavelength of 450 nm. Therefore, the semiconductor nanoparticle complex cured membrane of the present invention can have the below-described sufficient value of absorbance even when the mass fraction of the semiconductor nanoparticles in the semiconductor nanoparticle complex cured membrane is less than 70% by mass and further less than 60% by mass.

Since the semiconductor nanoparticle complex cured membrane of the present invention contains a semiconductor nanoparticle complex having a high absorbance at a high mass fraction, the absorbance of the semiconductor nanoparticle complex cured membrane can be increased. When the semiconductor nanoparticle complex cured membrane has a thickness of 10 μm, the absorbance with respect to light having a wavelength of 450 nm from the normal direction of the semiconductor nanoparticle complex cured membrane is preferably 1.0 or more, more preferably 1.3 or more, and even more preferably 1.5 or more.

Further, since the semiconductor nanoparticle complex cured membrane of the present invention includes a semiconductor nanoparticle complex having high light emission characteristics, it is possible to provide a semiconductor nanoparticle complex cured membrane having high light emission characteristics. The fluorescence quantum yield of the semiconductor nanoparticle complex cured membrane is preferably 70% or more, and more preferably 80% or more.

The thickness of the semiconductor nanoparticle complex cured membrane is preferably 50 μm or less, more preferably 20 μm or less, and even more preferably 10 μm or less in order to miniaturize the device in which the semiconductor nanoparticle complex cured membrane is to be used.

### (Semiconductor Nanoparticle Complex Patterning Membrane and Display Element)

The semiconductor nanoparticle complex patterning membrane of the present invention can be obtained by forming a membrane-shaped pattern of the above-mentioned semiconductor nanoparticle complex composition or dilution composition. A method for patterning the semiconductor nanoparticle complex composition and the dilution composition is not particularly limited, and examples thereof include spin coating, bar coating, inkjet, screen printing, photolithography, and the like.

The display element of the present invention uses the semiconductor nanoparticle complex patterning membrane of the present invention. For example, by using the semiconductor nanoparticle complex patterning membrane as a wavelength conversion layer, it is possible to provide a display element having excellent fluorescence quantum yield.

The semiconductor nanoparticle complex composition of the present invention has the following constitution.

(1) A semiconductor nanoparticle complex composition in which a semiconductor nanoparticle complex is dispersed in a dispersion medium, wherein
the semiconductor nanoparticle complex has a semiconductor nanoparticle and a ligand coordinated to the surface of the semiconductor nanoparticle;
the ligand includes an organic group;
the dispersion medium is a monomer or a prepolymer;
the semiconductor nanoparticle complex composition further includes a crosslinking agent; and
a mass fraction of the semiconductor nanoparticle in the semiconductor nanoparticle complex composition is 30% by mass or more.

(2) The semiconductor nanoparticle complex composition as described in (1) hereinabove, wherein the mass fraction of the semiconductor nanoparticle in the semiconductor nanoparticle complex composition is 40% by mass or more.

(3) The semiconductor nanoparticle complex composition as described in (1) or (2) hereinabove, wherein
when the semiconductor nanoparticle complex composition is formed into a membrane having a thickness of 10 μm, an absorbance of the membrane with respect to light having a wavelength of 450 nm from the normal direction of the membrane is 1.0 or more.

(4) The semiconductor nanoparticle complex composition as described in any one of (1) to (3) hereinabove, wherein
the mass ratio of the ligand to the semiconductor nanoparticle (ligand/semiconductor nanoparticle) is 0.05 to 0.50.

(5) The semiconductor nanoparticle complex composition as described in any one of (1) to (4) hereinabove, wherein
the mass ratio of the ligand to the semiconductor nanoparticle (ligand/semiconductor nanoparticle) is 0.10 to 0.40.

(6) The semiconductor nanoparticle complex composition as described in any one of (1) to (5) hereinabove, wherein
the ligand includes a hydrocarbon group which may have a substituent or a heteroatom, and a coordinating group.

(7) The semiconductor nanoparticle complex composition as described in any one of (1) to (6) hereinabove, wherein
the ligand has one or more groups selected from an ether group, an ester group and an amide group.

(8) The semiconductor nanoparticle complex composition as described in any one of (1) to (7) hereinabove, wherein
the ligand further includes a coordinating group, and
the organic group has a vinyl group and/or a vinylidene group.

(9) The semiconductor nanoparticle complex composition as described in any one of (1) to (8) hereinabove, wherein
the average particle diameter of the semiconductor nanoparticles is 10 nm or less.

(10) The semiconductor nanoparticle complex composition as described in any one of (1) to (9) hereinabove, wherein
the average particle diameter of the semiconductor nanoparticles is 7 nm or less.

(11) The semiconductor nanoparticle complex composition as described in any one of (1) to (10) hereinabove, wherein
a fluorescence quantum yield of the semiconductor nanoparticle complex composition is 60% or more.

(12) The semiconductor nanoparticle complex composition as described in any one of (1) to (11) hereinabove, wherein
a fluorescence quantum yield of the semiconductor nanoparticle complex composition is 70% or more.

(13) The semiconductor nanoparticle complex composition as described in any one of (1) to (12) hereinabove, wherein
the molecular weight of the ligand is 50 or more and 600 or less.

(14) The semiconductor nanoparticle complex composition as described in any one of (1) to (13) hereinabove, wherein
the molecular weight of the ligand is 50 or more and 450 or less.

(15) The semiconductor nanoparticle complex composition as described in any one of (1) to (14) hereinabove, wherein
the ligand has one or more mercapto groups.

(16) The semiconductor nanoparticle complex composition as described in any one of (1) to (15) hereinabove, wherein
the ligand has two or more mercapto groups.

(17) The semiconductor nanoparticle complex composition as described in any one of (1) to (16) hereinabove, wherein
there are two or more types of ligands.

(18) The semiconductor nanoparticle complex composition as described in any one of (1) to (17) hereinabove, wherein
the semiconductor nanoparticle includes In and P.

(19) The semiconductor nanoparticle complex composition as described in any one of (1) to (18) hereinabove, wherein
Zn is contained on the surface of the semiconductor nanoparticle.

(20) The semiconductor nanoparticle complex composition as described in any one of (1) to (19) hereinabove, wherein
a fluorescence quantum yield of the semiconductor nanoparticle complex is 80% or more.

(21) The semiconductor nanoparticle complex composition as described in any one of (1) to (20) hereinabove, wherein
a full width at half maximum of an emission spectrum of the semiconductor nanoparticle complex is 38 nm or less.

The dilution composition of the present invention has the following configuration.

(22) A dilution composition obtained by diluting the semiconductor nanoparticle complex composition as described in any one of (1) to (21) hereinabove with an organic solvent.

(23) The dilution composition as described in (22) hereinabove, wherein the organic solvent is a glycol ether and/or a glycol ether ester.

The semiconductor nanoparticle complex cured membrane of the present invention has the following configuration.

(24) A semiconductor nanoparticle complex cured membrane obtained by curing the semiconductor nanoparticle complex composition as described in any one of (1) to (21) hereinabove, or the dilution composition as described in (22) or (23) hereinabove.

The semiconductor nanoparticle complex patterning membrane of the present invention has the following configuration.

(25) A semiconductor nanoparticle complex patterning membrane formed by patterning the semiconductor nanoparticle complex composition as described in any one of (1) to (21) hereinabove, or the dilution composition as described in (22) or (23) hereinabove.

The display element of the present invention has the following configuration.

(26) A display device including the semiconductor nanoparticle complex patterning membrane as described in (25) hereinabove.

The semiconductor nanoparticle complex dispersion liquid of the present invention has the following configuration.

<1> A semiconductor nanoparticle dispersion liquid in which a semiconductor nanoparticle complex in which a ligand is coordinated to the surface of a semiconductor nanoparticle is dispersed in a dispersion medium, wherein
when the concentration of an inorganic component of the semiconductor nanoparticle complex in the dispersion liquid is 1 mg/mL, an absorbance at an optical path length of 1 cm is 0.6 or more with respect to light having a wavelength of 450 nm; and
the ligand includes an organic group.

<2> The semiconductor nanoparticle dispersion liquid as described in <1> hereinabove, wherein
an SP value of the dispersion medium is 8.5 or more.

<3> The semiconductor nanoparticle dispersion liquid as described in <1> or <2> hereinabove, wherein
an SP value of the dispersion medium is 9.0 or more.

<4> The semiconductor nanoparticle dispersion liquid as described in any one of <1> to <3> hereinabove, wherein
the dispersion medium is one dispersion medium or a mixture of two or more dispersion media selected from a glycol ether and a glycol ether ester.

<5> The semiconductor nanoparticle dispersion liquid as described in any one of <1> to <4> hereinabove, wherein
the dispersion medium is PGMEA or PGME.

<6> The semiconductor nanoparticle dispersion liquid as described in any one of <1> to <5> hereinabove, wherein
a mass ratio of the ligand to the semiconductor nanoparticle (ligand/semiconductor nanoparticle) is 0.05 to 0.50.

<7> The semiconductor nanoparticle dispersion liquid as described in any one of <1> to <6> hereinabove, wherein
a mass ratio of the ligand to the semiconductor nanoparticle (ligand/semiconductor nanoparticle) is 0.10 to 0.40.

<8> The semiconductor nanoparticle dispersion liquid as described in any one of <1> to <7> hereinabove, wherein
the average particle diameter of the semiconductor nanoparticles is 10 nm or less.

<9> The semiconductor nanoparticle dispersion liquid as described in any one of <1> to <8> hereinabove, wherein
the average particle diameter of the semiconductor nanoparticles is 7 nm or less.

<10> The semiconductor nanoparticle dispersion liquid as described in any one of <1> to <9> hereinabove, wherein
the ligand includes a hydrocarbon group which may have a substituent or a heteroatom, and a coordinating group.

<11> The semiconductor nanoparticle dispersion liquid as described in any one of <1> to <10> hereinabove, wherein
the molecular weight of the ligand is 50 or more and 600 or less.

<12> The semiconductor nanoparticle dispersion liquid as described in any one of <1> to <11> hereinabove, wherein
the molecular weight of the ligand is 50 or more and 450 or less.

<13> The semiconductor nanoparticle dispersion liquid as described in any one of <1> to <12> hereinabove, wherein
the ligand has at least one or more mercapto groups.

<14> The semiconductor nanoparticle dispersion liquid as described in any one of <1> to <13> hereinabove, wherein
the ligand further includes a coordinating group, and
the organic group has one or more groups selected from an ether group, an ester group and an amide group.

<15> The semiconductor nanoparticle dispersion liquid as described in any one of <1> to <14> hereinabove, wherein
the ligand further includes a coordinating group, and
the organic group has a vinyl group and/or a vinylidene group.

<16> The semiconductor nanoparticle dispersion liquid as described in any one of <1> to <15> hereinabove, wherein
the ligand has two or more mercapto groups.

<17> The semiconductor nanoparticle dispersion liquid as described in any one of <1> to <16> hereinabove, wherein
there are two or more types of ligands.

<18> The semiconductor nanoparticle dispersion liquid as described in any one of <1> to <17> hereinabove, wherein
Zn is contained on the surface of the semiconductor nanoparticle.

<19> The semiconductor nanoparticle dispersion liquid as described in any one of <1> to <18> hereinabove, wherein
the semiconductor nanoparticle includes In and P.

<20> The semiconductor nanoparticle dispersion liquid as described in any one of <1> to <19> hereinabove, wherein
a fluorescence quantum yield of the semiconductor nanoparticle complex is 80% or more.

<21> The semiconductor nanoparticle dispersion liquid as described in any one of <1> to <20> hereinabove, wherein
a full width at half maximum of an emission spectrum of the semiconductor nanoparticle complex is 38 nm or less.

The semiconductor nanoparticle complex cured membrane of the present invention has the following configuration.

[1]A semiconductor nanoparticle complex cured membrane in which a semiconductor nanoparticle complex is dispersed in a polymer matrix, wherein
the semiconductor nanoparticle complex has a semiconductor nanoparticle and a ligand coordinated to the surface of the semiconductor nanoparticle;
the ligand includes an organic group;
the polymer matrix is crosslinked by a crosslinking agent; and
a mass fraction of the semiconductor nanoparticle in the semiconductor nanoparticle complex cured membrane is 30% by mass or more.

[2] The semiconductor nanoparticle complex cured membrane as described in [1] hereinabove, wherein
the semiconductor nanoparticle complex cured membrane further includes a scattering agent.

[3] The semiconductor nanoparticle complex cured membrane as described in [1] or [2] hereinabove, wherein
the mass fraction of the semiconductor nanoparticle in the semiconductor nanoparticle complex cured membrane is 40% by mass or more.

[4] The semiconductor nanoparticle complex cured membrane as described in any one of [1] to [3] hereinabove, wherein
when the semiconductor nanoparticle complex cured membrane is formed to have a thickness of 10 μm, an absorbance of the semiconductor nanoparticle complex cured membrane with respect to light having a wavelength of 450 nm from the normal direction of the membrane is 1.0 or more.

[5] The semiconductor nanoparticle complex cured membrane as described in any one of [1] to [4] hereinabove, wherein
when the semiconductor nanoparticle complex cured membrane is formed to have a thickness of 10 μm, an absorbance of the semiconductor nanoparticle complex cured membrane with respect to light having a wavelength of 450 nm from the normal direction of the membrane is 1.5 or more.

[6] The semiconductor nanoparticle complex cured membrane as described in any one of [2] to [5] hereinabove, wherein
the scattering agent is a metal oxide.

[7] The semiconductor nanoparticle complex cured membrane as described in any one of [1] to [6] hereinabove, wherein
the mass ratio of the ligand to the semiconductor nanoparticle (ligand/semiconductor nanoparticle) is 0.05 to 0.50.

[8] The semiconductor nanoparticle complex cured membrane as described in any one of [1] to [7] hereinabove, wherein
the mass ratio of the ligand to the semiconductor nanoparticle (ligand/semiconductor nanoparticle) is 0.10 to 0.40.

[9] The semiconductor nanoparticle complex cured membrane as described in any one of [1] to [8] hereinabove, wherein
the ligand includes an organic group which is a hydrocarbon group which may have a substituent or a heteroatom, and a coordinating group.

[10] The semiconductor nanoparticle complex cured membrane as described in any one of [1] to [9] hereinabove, wherein
the ligand has one or more groups selected from an ether group, an ester group and an amide group.

[11] The semiconductor nanoparticle complex cured membrane as described in any one of [1] to [10] hereinabove, wherein
the ligand further includes a coordinating group; and
the organic group has a vinyl group and/or a vinylidene group.

[12] The semiconductor nanoparticle complex cured membrane as described in any one of [1] to [11] hereinabove, wherein
the average particle diameter of the semiconductor nanoparticles is 10 nm or less.

[13] The semiconductor nanoparticle complex cured membrane as described in any one of [1] to [12] hereinabove, wherein
the average particle diameter of the semiconductor nanoparticles is 7 nm or less.

[14] The semiconductor nanoparticle complex cured membrane as described in any one of [1] to [13] hereinabove, wherein
a fluorescence quantum yield of the semiconductor nanoparticle complex cured membrane is 70% or more.

[15] The semiconductor nanoparticle complex cured membrane as described in any one of [1] to [14] hereinabove, wherein
the molecular weight of the ligand is 50 or more and 600 or less.

[16] The semiconductor nanoparticle complex cured membrane as described in any one of [1] to [15] hereinabove, wherein
the molecular weight of the ligand is 50 or more and 450 or less.

[17] The semiconductor nanoparticle complex cured membrane as described in any one of [1] to [16] hereinabove, wherein
the ligand has one or more mercapto groups.

[18] The semiconductor nanoparticle complex cured membrane as described in any one of [1] to [17] hereinabove, wherein
the ligand has two or more mercapto groups.

[19] The semiconductor nanoparticle complex cured membrane as described in any one of [1] to [18] hereinabove, wherein
there are two or more types of ligands.

[20] The semiconductor nanoparticle complex cured membrane as described in any one of [1] to [19] hereinabove, wherein
the semiconductor nanoparticle includes In and P.

[21] The semiconductor nanoparticle complex cured membrane as described in any one of [1] to [20] hereinabove, wherein
Zn is contained on the surface of the semiconductor nanoparticle.

[22] The semiconductor nanoparticle complex cured membrane as described in any one of [1] to [21] hereinabove, wherein
a fluorescence quantum yield of the semiconductor nanoparticle complex is 80% or more.

[23] The semiconductor nanoparticle complex cured membrane as described in any one of [1] to [22] hereinabove, wherein
the full width at half maximum of the emission spectrum of the semiconductor nanoparticle complex is 38 nm or less.

[24] The semiconductor nanoparticle complex cured membrane as described in any one of [1] to [23] hereinabove, wherein
the thickness of the semiconductor nanoparticle complex cured membrane is 50 μm or less.

The semiconductor nanoparticle complex of the present invention adopts the following configuration.

<<1>> A semiconductor nanoparticle complex in which a ligand is coordinated to the surface of a semiconductor nanoparticle, wherein
the ligand includes an organic group; and
the mass ratio of the ligand to the semiconductor nanoparticle (ligand/semiconductor nanoparticle) is 0.05 to 0.50.

<<2>> The semiconductor nanoparticle complex as described in <<1>> hereinabove, wherein
the mass ratio of the ligand to the semiconductor nanoparticles is 0.10 to 0.40.

<<3>> The semiconductor nanoparticle complex as described in <<1>> or <<2>> hereinabove, wherein
Zn is contained on the surface of the semiconductor nanoparticle.

<<4>> The semiconductor nanoparticle complex as described in any one of <<1>> to <<3>> hereinabove, wherein
the semiconductor nanoparticle includes In and P.

<<5>> The semiconductor nanoparticle complex as described in any one of <<1>> to <<4>> hereinabove, wherein
the average particle diameter of the semiconductor nanoparticles is 10 nm or less.

<<6>> The semiconductor nanoparticle complex as described in any one of <<1>> to <<5>> hereinabove, wherein
the average particle diameter of the semiconductor nanoparticles is 7 nm or less.

<<7>> The semiconductor nanoparticle complex as described in any one of <<1>> to <<6>> hereinabove, wherein
a fluorescence quantum yield of the semiconductor nanoparticle complex is 80% or more.

<<8>> The semiconductor nanoparticle complex as described in any one of <<1>> to <<7>> hereinabove, wherein
a full width at half maximum of an emission spectrum of the semiconductor nanoparticle complex is 38 nm or less.

<<9>> The semiconductor nanoparticle complex as described in any one of <<1>> to <<8>> hereinabove, wherein
the ligand includes a monovalent hydrocarbon group which may have a substituent or a heteroatom.

<<10>> The semiconductor nanoparticle complex as described in any one of <<1>> to <<9>> hereinabove, wherein
the molecular weight of the ligand is 50 or more and 600 or less.

<<11>> The semiconductor nanoparticle complex as described in any one of <<1>> to <<10>> hereinabove, wherein
the molecular weight of the ligand is 50 or more and 450 or less.

<<12>> The semiconductor nanoparticle complex as described in any one of <<1>> to <<11>> hereinabove, wherein
the ligand includes at least one or more mercapto groups.

<<13>> The semiconductor nanoparticle complex as described in any one of <<1>> to <<12>> hereinabove, wherein
the ligand further includes a coordinating group; and
the organic group has one or more groups selected from an ether group, an ester group and an amide group.

<<14>> The semiconductor nanoparticle complex as described in any one of <<1>> to <<13>> hereinabove, wherein
the ligand further includes a coordinating group, and
the organic group has a vinyl group and/or a vinylidene group.

<<15>> The semiconductor nanoparticle complex as described in any one of <<1>> to <<14>> hereinabove, wherein
the ligand has two or more mercapto groups.

<<16>> The semiconductor nanoparticle complex as described in any one of <<1>> to <<15>> hereinabove, wherein
there are two or more types of ligands.

The configurations and/or methods set forth in the present description are illustrated by way of example and can be changed in a variety of ways. Therefore, it can be understood that specific examples or embodiments thereof should not be considered to be limiting. The particular procedure or method set forth in the present description may represent one of a number of processing methods. Thus, various operations explained and/or described can be performed in the order explained and/or described, or can be omitted. Similarly, the order of the above methods can be changed.

The subject matter of the present disclosure is inclusive the various methods, systems and configurations disclosed in the present description, as well as any new and non-trivial combinations and secondary combinations of other features, functions, operations, and/or properties, as well as any equivalents thereof.

### EXAMPLES

Hereinafter, the present invention will be specifically described with reference to Examples and Comparative Examples, but the present invention is not limited thereto.

### Example 1

### (Synthesis of Semiconductor Nanoparticles)

Semiconductor nanoparticles were synthesized according to the following method.

### —Preparation of Precursor—

### —Preparation of Zn Precursor Solution—

A total of 40 mmol of zinc oleate and 75 mL of octadecene were mixed and heated in vacuum at 110° C. for 1 h to prepare a Zn precursor of [Zn]=0.4 M.

### —Preparation of Se Precursor (Trioctylphosphine Selenide)—

A total of 22 mmol of selenium powder and 10 mL of trioctylphosphine were mixed in nitrogen and stirred until complete dissolution to obtain trioctylphosphine selenide of [Se]=2.2 M.

### —Preparation of S Precursor (Trioctylphosphine Sulfide)—

A total of 22 mmol of sulfur powder and 10 mL of trioctylphosphine were mixed in nitrogen and stirred until complete dissolution to obtain trioctylphosphine sulfide of [S]=2.2 M.

### —Formation of Core—

Indium acetate (0.3 mmol) and zinc oleate (0.6 mmol) were added to a mixture of oleic acid (0.9 mmol), 1-dodecanethiol (0.1 mmol) and octadecene (10 mL), followed by heating to about 120° C. and reacting for 1 h under vacuum (<20 Pa). The mixture reacted under vacuum was placed in a nitrogen atmosphere at 25° C., tris(trimethylsilyl) phosphine (0.2 mmol) was added thereto, and then the mixture was heated to about 300° C. and reacted for 10 min. The reaction liquid was cooled to 25° C., octanoic chloride (0.45 mmol) was injected thereinto, and the reaction liquid was heated at about 250° C. for 30 min and then cooled to 25° C.

### —Formation of Shell—

The core dispersion liquid was heated to 200° C., 0.75 mL of the Zn precursor solution and 0.3 mmol of trioctylphosphine selenide were added at the same time and reacted for 30 min to form a ZnSe shell on the surface of InP-based semiconductor nanoparticle. Further, 1.5 mL of the Zn precursor solution and 0.6 mmol of trioctylphosphine sulfide were added, the temperature was raised to 250° C., and the mixture was reacted for 1 h to form a ZnS shell.

### —Purification of Semiconductor Nanoparticles—

The reaction solution of the semiconductor nanoparticles obtained by the synthesis was added to acetone, mixed well, and then centrifuged. The centrifugal acceleration was 4000 G. The precipitate was collected, and normal hexane was added to the precipitate to prepare a dispersion liquid. This operation was repeated several times to obtain purified semiconductor nanoparticles.

### (Preparation of Semiconductor Nanoparticle Complex)

A semiconductor nanoparticles-1-octadecene dispersion liquid was prepared in a flask by dispersing the purified semiconductor nanoparticles in 1-octadecene so as to obtain a mass ratio of the nanoparticles of 10% by mass. A total of 10.0 g of the prepared semiconductor nanoparticles-1-octadecene dispersion liquid was placed in a flask, 3.5 g of triethylene glycol monomethylthiol (TEG-SH) and 0.5 g of dodecanethiol were added, and stirring was performed at 110° C. for 60 min under a nitrogen atmosphere, followed by cooling to 25° C. to obtain a semiconductor nanoparticle complex.

The reaction solution was transferred to a centrifuge tube and centrifuged at 4000 G for 20 min to separate into a transparent 1-octadecene phase and a semiconductor nanoparticle complex phase. The 1-octadecene phase was removed and the remaining semiconductor nanoparticle complex phase was collected.

### —Purification of Semiconductor Nanoparticle Complex—

A total of 5.0 mL of acetone was added to the obtained semiconductor nanoparticle complex phase to prepare a dispersion liquid. A total of 50 mL of normal hexane was added to the obtained dispersion liquid, followed by centrifugation at 4000 G for 20 min. After centrifugation, the clear supernatant was removed and the precipitate was collected. This operation was repeated several times to obtain a purified semiconductor nanoparticle complex.

### (Measurements)

The optical characteristics of the obtained semiconductor nanoparticle complex were measured.

As described hereinabove, the optical properties were measured using a fluorescence quantum yield measurement system (QE-2100, manufactured by Otsuka Electronics Co., Ltd.). The obtained semiconductor nanoparticle complex was dispersed in PGMEA (propylene glycol monomethyl ether acetate), and a single light of 450 nm was used to obtain an emission spectrum. The fluorescence quantum yield (QY) and full width at half maximum (FWHM) were calculated from the emission spectrum after re-excitation correction in which a re-excitation fluorescence emission spectrum corresponding to fluorescence emission by re-excitation was excluded from the emission spectrum obtained herein.

### (Semiconductor Nanoparticle Complex Dispersion Liquid)

The purified semiconductor nanoparticle complex was heated to 550° C. by differential thermogravimetric analysis (DTA-TG), then held for 10 min, and cooled. The residual mass after the analysis was taken as the mass of the semiconductor nanoparticles, and the mass ratio of the semiconductor nanoparticles to the semiconductor nanoparticle complex was confirmed from this value.

With reference to the mass ratio, PGMEA (SP value 9.41) was added to the semiconductor nanoparticle complex so that the mass fraction of the semiconductor nanoparticles in the semiconductor nanoparticle complex dispersion liquid was 1 mg/mL, thereby obtaining a nanoparticle complex dispersion liquid. This semiconductor nanoparticle complex dispersion liquid was placed in an optical cell having an optical path length of 1 cm, and the absorbance at 450 nm was measured using a visible ultraviolet spectrophotometer (V670 manufactured by JASCO Corporation), and this was designated as OD₄₅₀.

### (Semiconductor Nanoparticle Complex Composition)

A total of 89 parts by mass of isobornyl acrylate, 10 parts by mass of trimethylolpropane triacrylate, and 1 part by mass of 2,2-dimethoxy-2-phenylacetophenone were mixed to obtain an ultraviolet-curable resin. The ultraviolet-curable resin and the semiconductor nanoparticle complex were mixed to obtain a semiconductor nanoparticle complex composition. At this time, the mass fraction of the semiconductor nanoparticles in the semiconductor nanoparticle complex composition was 40% by mass.

### (Semiconductor Nanoparticle Complex Cured Membrane)

A membrane of the above-mentioned semiconductor nanoparticle complex composition was formed on glass by spin coating followed by heating at 90° C. for 3 min to volatilize the solvent. After photocuring by irradiating with ultraviolet rays in the air, the membrane was baked at 200° C. for 20 min to obtain a semiconductor nanoparticle complex cured membrane.

The obtained semiconductor nanoparticle complex cured membrane was irradiated with light having a wavelength of 450 nm from the normal direction of the semiconductor nanoparticle complex cured membrane and the absorbance per 5 μm of the semiconductor nanoparticle complex cured membrane was measured by using a visible ultraviolet spectrophotometer (V670 manufactured by JASCO Corporation) in the same manner as that of the semiconductor nanoparticle complex dispersion liquid. The absorbance at this time is shown in the table.

Furthermore, the fluorescence quantum yield of the semiconductor nanoparticle complex cured membrane was measured using a quantum yield measurement system (manufactured by Otsuka Electronics, QE-2100) in the same manner as that of the semiconductor nanoparticle complex. The fluorescence quantum yield of the semiconductor nanoparticle complex cured membranes is shown in Tables 1 to 3.

### Example 2

A semiconductor nanoparticle complex was obtained by adding 4.0 g of methyl 3-mercaptopropionate (MPA-Me) instead of TEG-SH in the method for preparing a semiconductor nanoparticle complex described in Example 1 hereinabove.

A semiconductor nanoparticle complex, a semiconductor nanoparticle complex dispersion liquid, a semiconductor nanoparticle complex composition, and a semiconductor nanoparticle complex cured membrane were prepared and physical characteristics thereof were evaluated in the same manner as in Example 1 except for the above.

### Example 3

A semiconductor nanoparticle complex was obtained by adding 4.0 g of 2-mercaptoethanol instead of TEG-SH in the method for preparing a semiconductor nanoparticle complex described in Example 1 hereinabove.

A semiconductor nanoparticle complex, a semiconductor nanoparticle complex dispersion liquid, a semiconductor nanoparticle complex composition, and a semiconductor nanoparticle complex cured membrane were prepared and physical characteristics thereof were evaluated in the same manner as in Example 1 except for the above.

### Example 4

A semiconductor nanoparticle complex was obtained by adding 3.5 g of methyl dihydrolipoate prepared by the method described hereinbelow instead of TEG-SH in the method for preparing a semiconductor nanoparticle complex described in Example 1 hereinabove.

A semiconductor nanoparticle complex, a semiconductor nanoparticle complex dispersion liquid, a semiconductor nanoparticle complex composition, and a semiconductor nanoparticle complex cured membrane were prepared and physical characteristics thereof were evaluated in the same manner as in Example 1 except for the above.

### —Preparation of Methyl Dihydrolipoate—

A total of 2.1 g (10 mmol) of dihydrolipoic acid was dissolved in 20 mL (49 mmol) of methanol, and 0.2 mL of concentrated sulfuric acid was added. The solution was refluxed under a nitrogen atmosphere for 1 h. The reaction solution was diluted with chloroform, and the solution was extracted with a 10% HCl aqueous solution, a 10% Na₂CO₃ aqueous solution, and a saturated NaCl aqueous solution in this order to collect the organic phase. The organic phase was concentrated by evaporation and purified by column chromatography using a hexane-ethyl acetate mixed solvent as a developing solvent to obtain methyl dihydrolipoate.

### Example 5

A semiconductor nanoparticle complex was obtained by adding 3.5 g of 6-mercaptohexyl acrylate prepared by the method described hereinbelow instead of TEG-SH in the method for preparing a semiconductor nanoparticle complex described in Example 1 hereinabove.

A semiconductor nanoparticle complex, a semiconductor nanoparticle complex dispersion liquid, a semiconductor nanoparticle complex composition, and a semiconductor nanoparticle complex cured membrane were prepared and physical characteristics thereof were evaluated in the same manner as in Example 1 except for the above.

### Preparation of 6-mercaptohexyl acrylate

A total of 1.34 g (10 mmol) of 2-aminoethanethiol and 1.7 mL (12 mmol) of triethylamine were placed in a 100 mL round bottom flask and dissolved in 30 mL of dehydrated dichloromethane. The solution was cooled to 0° C., and 0.81 mL (10 mmol) of acryloyl chloride was slowly added dropwise under a nitrogen atmosphere, while taking care that the temperature of the solution did not exceed 5° C. After completion of the dropping, the reaction solution was heated to room temperature and stirred for 1 h. The reaction solution was filtered and the filtrate was diluted with chloroform. The filtrate was extracted with a 10% HCl aqueous solution, a 10% Na₂CO₃ aqueous solution, and a saturated NaCl aqueous solution in this order to collect the organic phase. The obtained organic phase was dried over magnesium sulfate and then filtered and concentrated by evaporation to obtain the desired 6-mercaptohexyl acrylate. In order to prevent the intramolecular reaction between the mercapto group and the acrylic group, the product was used for the preparation of the semiconductor nanoparticle complex immediately after purification.

### Example 6

A semiconductor nanoparticle complex was obtained by adding 3.5 g of N-acetyl-N-(2-mercaptoethyl)propanamide prepared by the method described hereinbelow instead of TEG-SH in the method for preparing a semiconductor nanoparticle complex described in Example 1 hereinabove.

Further, a semiconductor nanoparticle complex composition was obtained by changing the monomer to a mixture of methacrylic acid, glycidyl methacrylate, and 2,2-azobis(2,4-dimethylvaleronitrile), and changing the crosslinking agent to PETA-SA (entaerythritol triacrylate succinic acid modified product) in the production of a semiconductor nanoparticle complex composition described in Example 1 hereinabove.

A semiconductor nanoparticle complex, a semiconductor nanoparticle complex dispersion liquid, a semiconductor nanoparticle complex composition, and a semiconductor nanoparticle complex cured membrane were prepared and physical characteristics thereof were evaluated in the same manner as in Example 1 except for the above.

### Preparation of N-acetyl-N-(2-mercaptoethyl)propanamide

A total of 1.2 g (10 mmol) of N-(2-sulfanylethyl)acetamide and 1.7 mL (12 mmol) of triethylamine were placed in a 100 mL round-bottom flask and dissolved in 30 mL of dehydrated dichloromethane. The solution was cooled to 0° C., and 0.87 mL (10 mmol) of propanoyl chloride was slowly added dropwise under a nitrogen atmosphere, while taking care that the temperature of the solution did not exceed 5° C. After completion of the dropping, the reaction solution was heated to room temperature and stirred for 2 h. The reaction solution was filtered and the filtrate was diluted with chloroform. The solution was extracted with a 10% HCl aqueous solution, a 10% Na₂CO₃ aqueous solution, and a saturated NaCl aqueous solution in this order to collect the organic phase. The organic phase was concentrated by evaporation and then purified by column chromatography using a mixed solvent of hexane-ethyl acetate as a developing solvent to obtain N-acetyl-N-(2-mercaptoethyl)propanamide.

### Example 7

A semiconductor nanoparticle complex was obtained by adding 3.5 g of N-acetyl-N-(2-mercaptoethyl)propanamide instead of TEG-SH in the method for preparing a semiconductor nanoparticle complex described in Example 1 hereinabove.

Further, a semiconductor nanoparticle complex composition was obtained by changing the monomer and the crosslinking agent to a mixture (a mass ratio of 50:50) of liquid A and liquid B of a transparent encapsulating resin for a photodevice (type “SCR-1011 (A/B)”, manufactured by Shin-Etsu Silicone Co., Ltd.), which is a thermosetting addition-reaction type silicone resin, in the production of a semiconductor nanoparticle complex composition.

Further, a semiconductor nanoparticle complex cured membrane was obtained by coating the semiconductor nanoparticle complex composition on glass by spin coating and heating at 150° C. for 5 h in the production of a semiconductor nanoparticle complex cured membrane.

A semiconductor nanoparticle complex, a semiconductor nanoparticle complex dispersion liquid, a semiconductor nanoparticle complex composition, and a semiconductor nanoparticle complex cured membrane were prepared and physical characteristics thereof were evaluated in the same manner as in Example 1 except for the above.

### Example 8

In the method for producing semiconductor nanoparticles described in Example 1 hereinabove, the amount of the Zn precursor solution used for forming the ZnS shell was changed to 1.0 mL, and the amount of trioctylphosphine sulfide was changed to 0.4 mmol. The average particle diameter of the semiconductor nanoparticles thus obtained (the above-mentioned Heywood diameter) was measured by TEM and found to be 3 nm.

Further, a semiconductor nanoparticle complex was obtained by adding 3.5 g of methyl dihydroate instead of TEG-SH in the method for preparing a semiconductor nanoparticle complex described in Example 1.

A semiconductor nanoparticle complex, a semiconductor nanoparticle complex dispersion liquid, a semiconductor nanoparticle complex composition, and a semiconductor nanoparticle complex cured membrane were prepared and physical characteristics thereof were evaluated in the same manner as in Example 1 except for the above.

### Example 9

In the method for producing semiconductor nanoparticles described in Example 1 hereinabove, the amount of the Zn precursor solution used for forming the ZnS shell was changed to 1.75 mL, and the amount of trioctylphosphine sulfide was changed to 0.7 mmol. The average particle diameter of the semiconductor nanoparticles thus obtained (the above-mentioned Heywood diameter) was measured by TEM and found to be 6 nm.

Further, a semiconductor nanoparticle complex was obtained by adding 3.5 g of PEG-SH (polyethylene glycol monomethyl ether thiol) prepared by the method described hereinbelow instead of TEG-SH in the method for preparing a semiconductor nanoparticle complex described in Example 1.

A semiconductor nanoparticle complex, a semiconductor nanoparticle complex dispersion liquid, a semiconductor nanoparticle complex composition, and a semiconductor nanoparticle complex cured membrane were prepared and physical characteristics thereof were evaluated in the same manner as in Example 1 except for the above.

### —Preparation of PEG-SH—

A total of 210 g of methoxy-PEG-OH (molecular weight 400) and 93 g of trimethylamine were placed in a flask and dissolved in 420 mL of THF (tetrahydrofuran). The solution was cooled to 0° C., and 51 g of methanesulfonic acid chloride was gradually added dropwise under a nitrogen atmosphere, while taking care that the temperature of the reaction solution did not exceed 5° C. due to the heat of reaction. Then, the reaction solution was heated to room temperature and stirred for 2 h. This solution was extracted with a chloroform-water system to collect the organic phase. The obtained solution was dried with magnesium sulfate, magnesium sulfate was removed by filtration, and the filtrate was concentrated by evaporation to obtain an oily intermediate. This was transferred to another flask, and 400 mL of 1.3 M aqueous thiourea solution was added under a nitrogen atmosphere. The solution was refluxed for 2 h, then 21 g of NaOH was added and the solution was refluxed for another 1.5 h. The reaction solution was cooled to room temperature, and a 1M HCl aqueous solution was added to reach pH=7 to neutralize the reaction solution. The obtained solution was extracted with a chloroform-water system to obtain the desired ligand (PEG-SH, molecular weight 400).

### Example 10

A semiconductor nanoparticle complex was obtained by adding 3.5 g of PEG-SH instead of TEG-SH in the method for preparing a semiconductor nanoparticle complex described in Example 1 hereinabove.

A semiconductor nanoparticle complex, a semiconductor nanoparticle complex dispersion liquid, a semiconductor nanoparticle complex composition, and a semiconductor nanoparticle complex cured membrane were prepared and physical characteristics thereof were evaluated in the same manner as in Example 1 except for the above.

### Example 11

In the method for producing semiconductor nanoparticles described in Example 1 hereinabove, the amount of the Zn precursor solution used for forming the ZnS shell was changed to 2.0 mL, and the amount of trioctylphosphine sulfide was changed to 0.9 mmol. The average particle diameter of the semiconductor nanoparticles thus obtained (the above-mentioned Heywood diameter) was measured by TEM and found to be 7 nm.

Further, a semiconductor nanoparticle complex was obtained by adding 3.5 g of N-acetyl-N-(2-mercaptoethyl)propanamide instead of TEG-SH in the method for preparing a semiconductor nanoparticle complex described in Example 1.

A semiconductor nanoparticle complex, a semiconductor nanoparticle complex dispersion liquid, a semiconductor nanoparticle complex composition, and a semiconductor nanoparticle complex cured membrane were prepared and physical characteristics thereof were evaluated in the same manner as in Example 1 except for the above.

### Example 12

In the method for producing semiconductor nanoparticles described in Example 1 hereinabove, the amount of the Zn precursor solution used for forming the ZnS shell was changed to 3.75 mL, and the amount of trioctylphosphine sulfide was changed to 1.5 mmol. The average particle diameter of the semiconductor nanoparticles thus obtained (the above-mentioned Heywood diameter) was measured by TEM and found to be 10 nm.

Further, a semiconductor nanoparticle complex was obtained by adding 3.5 g of N-acetyl-N-(2-mercaptoethyl)propanamide instead of TEG-SH in the method for preparing a semiconductor nanoparticle complex described in Example 1.

A semiconductor nanoparticle complex, a semiconductor nanoparticle complex dispersion liquid, a semiconductor nanoparticle complex composition, and a semiconductor nanoparticle complex cured membrane were prepared and physical characteristics thereof were evaluated in the same manner as in Example 1 except for the above.

### Example 13

In the method for producing semiconductor nanoparticles described in Example 1 hereinabove, the amount of the Zn precursor solution used for forming the ZnS shell was changed to 3.75 mL, and the amount of trioctylphosphine sulfide was changed to 1.5 mmol. The average particle diameter of the semiconductor nanoparticles thus obtained (the above-mentioned Heywood diameter) was measured by TEM and found to be 13 nm.

Further, a semiconductor nanoparticle complex was obtained by adding 3.5 g of PEG-SH instead of TEG-SH in the method for preparing a semiconductor nanoparticle complex described in Example 1 hereinabove.

A semiconductor nanoparticle complex, a semiconductor nanoparticle complex dispersion liquid, a semiconductor nanoparticle complex composition, and a semiconductor nanoparticle complex cured membrane were prepared and physical characteristics thereof were evaluated in the same manner as in Example 1 except for the above.

### Example 14

In the method for producing semiconductor nanoparticles described in Example 1 hereinabove, the amount of the Zn precursor solution used for forming the ZnSe shell was changed to 1.5 mL, and the amount of trioctylphosphine selenide was changed to 0.6 mmol. Further, the amount of the Zn precursor solution used for forming the ZnS shell was changed to 4.5 mL, and the amount of trioctylphosphine sulfide was changed to 1.8 mmol. The average particle diameter of the semiconductor nanoparticles thus obtained (the above-mentioned Heywood diameter) was measured by TEM and found to be 13 nm.

Further, a semiconductor nanoparticle complex was obtained by adding 3.5 g of PEG-SH instead of TEG-SH in the method for preparing a semiconductor nanoparticle complex described in Example 1 hereinabove.

A semiconductor nanoparticle complex, a semiconductor nanoparticle complex dispersion liquid, a semiconductor nanoparticle complex composition, and a semiconductor nanoparticle complex cured membrane were prepared and physical characteristics thereof were evaluated in the same manner as in Example 1 except for the above.

### Example 15

A semiconductor nanoparticle complex was obtained by adding 6.5 g of PEG-COOH (molecular weight 750) prepared by the method described hereinbelow instead of TEG-SH in the method for preparing a semiconductor nanoparticle complex described in Example 1 hereinabove.

A semiconductor nanoparticle complex, a semiconductor nanoparticle complex dispersion liquid, a semiconductor nanoparticle complex composition, and a semiconductor nanoparticle complex cured membrane were prepared and physical characteristics thereof were evaluated in the same manner as in Example 1 except for the above.

When a semiconductor nanoparticle complex cured membrane was prepared in the same manner as in Example 1, the membrane was not cured.

### —Preparation of PEG-COOH (Molecular Weight 750)—

Methoxy-PEG-OH (molecular weight 700, 26 g) was dissolved in toluene (100 mL) at 60° C., 4.2 g of potassium tert-butoxide was added, and the reaction was conducted for 6 h. Then 5.5 g of ethyl bromoacetate was added to the mixture and the hydroxyl groups in the PEG were protected by ethyl acetate groups. The mixture was filtered and the filtrate was precipitated in diethyl ether. The precipitate was dissolved in 1M NaOH solution (40 mL), NaCl (10 g) was added, and the mixture was stirred at room temperature for 1 h to remove the ethyl group at the end of PEG. This solution was adjusted to pH 3.0 by adding 6M HCl. The obtained solution was extracted with a chloroform-water system to obtain PEG-COOH having a molecular weight of 750.

### Example 16

A semiconductor nanoparticle complex was obtained by adding 8.5 g of PEG-COOH (molecular weight 1000) prepared by the method described hereinbelow instead of TEG-SH in the method for preparing a semiconductor nanoparticle complex described in Example 1 hereinabove.

A semiconductor nanoparticle complex, a semiconductor nanoparticle complex dispersion liquid, a semiconductor nanoparticle complex composition, and a semiconductor nanoparticle complex cured membrane were prepared and physical characteristics thereof were evaluated in the same manner as in Example 1 except for the above.

When a semiconductor nanoparticle complex cured membrane was prepared in the same manner as in Example 1, the membrane was not cured.

### —Preparation of PEG-COOH (Molecular Weight 1000)—

Methoxy-PEG-OH (molecular weight 950, 36 g) was dissolved in toluene (100 mL) at 60° C., 4.2 g of potassium tert-butoxide was added, and the reaction was conducted for 6 h. Then 5.5 g of ethyl bromoacetate was added to the mixture and the hydroxyl groups in the PEG were protected by ethyl acetate groups. The mixture was filtered and the filtrate was precipitated in diethyl ether. The precipitate was dissolved in 1M NaOH solution (40 mL), NaCl (10 g) was added, and the mixture was stirred at room temperature for 1 h to remove the ethyl group at the end of PEG. This solution was adjusted to pH 3.0 by adding 6M HCl. The obtained solution was extracted with a chloroform-water system to obtain PEG-COOH having a molecular weight of 1000.

### Example 17

A semiconductor nanoparticle complex was obtained by adding 6.5 g of PEG-COOH (molecular weight 750) instead of TEG-SH in the method for preparing a semiconductor nanoparticle complex described in Example 1 hereinabove.

A semiconductor nanoparticle complex, a semiconductor nanoparticle complex dispersion liquid, a semiconductor nanoparticle complex composition, and a semiconductor nanoparticle complex cured membrane were prepared and physical characteristics thereof were evaluated in the same manner as in Example 1 except for the above.

The upper limit of the mass fraction of the semiconductor nanoparticles in the semiconductor nanoparticle complex composition and the semiconductor nanoparticle complex cured membrane was 25%.

### Example 18

A semiconductor nanoparticle complex was obtained by adding 3.5 g of N-acetyl-N-(2-mercaptoethyl)propanamide instead of TEG-SH in the method for preparing a semiconductor nanoparticle complex described in Example 1 hereinabove.

A semiconductor nanoparticle complex, a semiconductor nanoparticle complex dispersion liquid, and a semiconductor nanoparticle complex composition were prepared and physical characteristics thereof were evaluated in the same manner as in Example 1 except for the above.

An attempt was made to prepare a cured membrane in the same manner as in Example 1 without adding a crosslinking agent in the preparation of a semiconductor nanoparticle complex cured membrane, but the membrane was not cured.

### Example 19

In the method for preparing a semiconductor nanoparticle complex described in Example 1 above, the operations were changed as follows.

A total of 10.0 g of a semiconductor nanoparticle hexane dispersion liquid in which purified semiconductor nanoparticles were dispersed in a hexane in a flask at a mass ratio of 10% by mass in a flask was placed in a flask, 10 mL of formamide and 10 mL of a 0.5% by mass ammonium sulfide aqueous solution were added, and stirring was performed at room temperature for 10 min under a nitrogen atmosphere to obtain a reaction solution including a semiconductor nanoparticle complex. The reaction solution was transferred to a centrifuge tube, 40 mL of acetone was added, and the mixture was centrifuged at 4000 G for 20 min to separate into a transparent solution layer and a semiconductor nanoparticle complex phase. The transparent solution phase was removed and the remaining semiconductor nanoparticle complex phase was collected.

In the method for purifying a semiconductor nanoparticle complex described in Example 1 above, acetone was changed to chloroform, and normal hexane was changed to acetone. The fluorescence quantum yield of the obtained semiconductor nanoparticle complex was 15%, and the full width at half maximum was 45 nm.

The obtained semiconductor nanoparticle complex was not dispersed in PGMEA. Furthermore, the semiconductor nanoparticle complex did not disperse in isobornyl acrylate.

Semiconductor nanoparticle complex compositions were obtained by mixing titanium oxide (diameter 300 nm) in an amount of 10% by mass with respect to the semiconductor nanoparticle complex of each of the above examples when the monomer and the semiconductor nanoparticle complex were mixed in the method for preparing the semiconductor nanoparticle complex composition, and then the semiconductor nanoparticle complex compositions were cured to obtain semiconductor nanoparticle complex cured membranes including a scattering agent. The absorbance of the semiconductor nanoparticle complex cured membranes including a scattering agent was measured by the method described above. The results are shown in Tables 1 to 3.

The meaning of the abbreviations shown in Table 1 is as follows.
DDT: Dodecanethiol
OA: Oleic acid

TABLE 1

| | Semiconductor | | | | | | |
|---|---|---|---|---|---|---|---|
| | nanoparticle | Semiconductor nanoparticle complex | | | | | |
| | Average | | Molecular | | | Fluorescent | Full width |
| | particle | | weight of | Other | Ligand/semiconductor | quantum | at half |
| No. | diameter (nm) | Ligand | ligand | ligands | nanoparticle | yield (%) | maximum (nm) |
| Example 1 | 5 | TEG-SH | 200 | DDT, OA | 0.33 | 86 | 37 |
| Example 2 | 5 | Methyl 3- | 130 | DDT, OA | 0.25 | 84 | 37 |
| | | mercaptopropionate | | | | | |
| Example 3 | 5 | 2-Mercaptoethanol | 78 | DDT, OA | 0.14 | 88 | 37 |
| Example 4 | 5 | Methyl | 223 | DDT, OA | 0.23 | 86 | 37 |
| | | dihydrolipoate | | | | | |
| Example 5 | 5 | 6-Mercaptohexyl | 188 | DDT, OA | 0.33 | 87 | 37 |
| | | acrylate | | | | | |
| Example 6 | 5 | N-acetyl-N-(2- | 175 | DDT, OA | 0.33 | 88 | 37 |
| | | mercaptoethyl)propanamide | | | | | |
| Example 7 | 5 | N-acetyl-N-(2- | 175 | DDT, OA | 0.33 | 84 | 37 |
| | | mercaptoethyl)propanamide | | | | | |
| Example 8 | 3 | Methyl | 223 | DDT, OA | 0.35 | 83 | 37 |
| | | dihydrolipoate | | | | | |
| Example 9 | 6 | PEG-SH | 400 | DDT, OA | 0.39 | 87 | 37 |
| Example 10 | 5 | PEG-SH | 400 | DDT, OA | 0.50 | 86 | 37 |
| Example 11 | 7 | N-acetyl-N-(2- | 175 | DDT, OA | 0.20 | 87 | 37 |
| | | mercaptoethyl)propanamide | | | | | |
| Example 12 | 10 | N-acetyl-N-(2- | 175 | DDT, OA | 0.15 | 88 | 38 |
| | | mercaptoethyl)propanamide | | | | | |
| Example 13 | 10 | PEG-SH | 400 | DDT, OA | 0.24 | 85 | 38 |
| Example 14 | 13 | PEG-SH | 400 | DDT, OA | 0.15 | 81 | 38 |
| Example 15 | 5 | PEG-COOH | 750 | DDT, OA | 1.02 | 87 | 37 |
| Example 16 | 5 | PEG-COOH | 1000 | DDT, OA | 1.29 | 83 | 37 |
| Example 17 | 5 | PEG-COOH | 750 | DDT, OA | 1.02 | 86 | 37 |
| Example 18 | 5 | N-acetyl-N-(2- | 175 | DDT, OA | 0.33 | 83 | 37 |
| | | mercaptoethy1)propanamide | | | | | |
| Example 19 | 5 | Ammonium sulfide | 51.1 | DDT, OA | 0.09 | 15 | 45 |

TABLE 2

| | Semiconductor | | | | |
|---|---|---|---|---|---|
| | nanoparticle complex | | | | |
| | dispersion liquid | | Semiconductor nanoparticle complex composition | | |
| | | Absorbance | | | Mass |
| | Dispersion | (measured | | | fraction |
| | medium | at 450 nm) | Dispersion medium | Crosslinking agent | (%) |
| Example 1 | PGMEA | 0.8 | IBOA | Trimethylolpropane | 40 |
| | | | | triacrylate | |
| Example 2 | PGMEA | 0.8 | IBOA | Trimethylolpropane | 40 |
| | | | | triacrylate | |
| Example 3 | PGMEA | 0.8 | IBOA | Trimethylolpropane | 40 |
| | | | | triacrylate | |
| Example 4 | PGMEA | 0.8 | IBOA | Trimethylolpropane | 40 |
| | | | | triacrylate | |
| Example 5 | PGMEA | 0.8 | IBOA | Trimethylolpropane | 40 |
| | | | | triacrylate | |
| Example 6 | PGMEA | 0.8 | Glycidyl methacrylate, | PETA-SA | 40 |
| | | | 2,2-azobis(2,4- | | |
| | | | dimethylvaleronitrile) | | |
| | | | methacrylate | | |
| Example 7 | PGMEA | 0.8 | SCR-1010A | SCR-1010B | 40 |
| Example 8 | PGMEA | 0.8 | IBOA | Trimethylolpropane | 40 |
| | | | | triacrylate | |
| Example 9 | PGMEA | 0.6 | IBOA | Trimethylolpropane | 40 |
| | | | | triacrylate | |
| Example 10 | PGMEA | 0.8 | IBOA | Trimethylolpropane | 35 |
| | | | | triacrylate | |
| Example 11 | PGMEA | 0.4 | IBOA | Trimethylolpropane | 40 |
| | | | | triacrylate | |
| Example 12 | PGMEA | 0.8 | IBOA | Trimethylolpropane | 40 |
| | | | | triacrylate | |
| Example 13 | PGMEA | 0.8 | IBOA | Trimethylolpropane | 40 |
| | | | | triacrylate | |
| Example 14 | PGMEA | 0.4 | IBOA | Trimethylolpropane | 40 |
| | | | | triacrylate | |
| Example 15 | PGMEA | 0.8 | IBOA | Trimethylolpropane | 25 |
| | | | | triacrylate | |
| Example 16 | PGMEA | 0.8 | IBOA | Trimethylolpropane | 25 |
| | | | | triacrylate | |
| Example 17 | PGMEA | 0.8 | IBOA | Trimethylolpropane | 25 |
| | | | | triacrylate | |
| Example 18 | PGMEA | 0.8 | IBOA | — | 30 |
| Example 19 | PGMEA | — | — | — | — |

TABLE 3

| | Semiconductor nanoparticle complex cured membrane | | | | | | |
|---|---|---|---|---|---|---|---|
| | | | | | | Absorbance | |
| | | | | | | (without | Absorbance (with |
| | | | | Fluorescent | Mass | scattering | scattering |
| | Polymer | Scattering | Curing | quantum | fraction | agent, membrane | agent, membrane |
| No. | matrix | agent | yes/no | yield (%) | (%) | thickness 10 μm) | thickness 10 μm) |
| Example 1 | Acryl | TiO₂ | yes | 73 | 40 | 1.2 | 1.6 |
| | polymer | | | | | | |
| Example 2 | Acryl | TiO₂ | yes | 75 | 40 | 1.1 | 1.5 |
| | polymer | | | | | | |
| Example 3 | Acryl | TiO₂ | yes | 77 | 40 | 1.2 | 1.5 |
| | polymer | | | | | | |
| Example 4 | Acryl | TiO₂ | yes | 72 | 40 | 1.2 | 1.6 |
| | polymer | | | | | | |
| Example 5 | Acryl | TiO₂ | yes | 74 | 40 | 1.2 | 1.6 |
| | polymer | | | | | | |
| Example 6 | Epoxy | TiO₂ | yes | 75 | 40 | 1.1 | 1.5 |
| | polymer | | | | | | |
| Example 7 | Silicone | TiO₂ | yes | 73 | 40 | 1.2 | 1.6 |
| | polymer | | | | | | |
| Example 8 | Acryl | TiO₂ | yes | 71 | 40 | 1.2 | 1.5 |
| | polymer | | | | | | |
| Example 9 | Acryl | TiO₂ | yes | 75 | 40 | 1.0 | 1.3 |
| | polymer | | | | | | |
| Example 10 | Acryl | TiO₂ | yes | 75 | 35 | 1.0 | 1.2 |
| | polymer | | | | | | |
| Example 11 | Acryl | TiO₂ | yes | 75 | 40 | 0.6 | 0.8 |
| | polymer | | | | | | |
| Example 12 | Acryl | TiO₂ | yes | 75 | 40 | 1.1 | 1.5 |
| | polymer | | | | | | |
| Example 13 | Acryl | TiO₂ | yes | 75 | 40 | 1.2 | 1.5 |
| | polymer | | | | | | |
| Example 14 | Acryl | TiO₂ | yes | 75 | 40 | 0.6 | 0.8 |
| | polymer | | | | | | |
| Example 15 | Acryl | TiO₂ | no | — | 25 | — | — |
| | polymer | | | | | | |
| Example 16 | Acryl | TiO₂ | no | — | 25 | — | — |
| | polymer | | | | | | |
| Example 17 | Acryl | TiO₂ | yes | 50 | 25 | 0.6 | 0.8 |
| | polymer | | | | | | |
| Example 18 | Acryl | TiO₂ | no | — | 30 | — | — |
| | polymer | | | | | | |
| Example 19 | — | — | — | — | — | — | — |

1. A semiconductor nanoparticle complex cured membrane in which a semiconductor nanoparticle complex is dispersed in a polymer matrix, wherein
the semiconductor nanoparticle complex has a semiconductor nanoparticle and a ligand coordinated to the surface of the semiconductor nanoparticle;
the ligand includes an organic group;
the organic group has at least one selected from the group consisting of a vinyl group, a vinylidene group, and a vinylene group;
the polymer matrix is crosslinked with the semiconductor nanoparticle composite by a crosslinking agent;
and
a mass fraction of the semiconductor nanoparticle in the semiconductor nanoparticle complex cured membrane is 30% by mass or more.

2. The semiconductor nanoparticle complex cured membrane according to claim 1, wherein
the semiconductor nanoparticle complex cured membrane further includes a scattering agent.

3. The semiconductor nanoparticle complex cured membrane according to claim 1, wherein
the mass fraction of the semiconductor nanoparticle in the semiconductor nanoparticle complex cured membrane is 40% by mass or more.

4. The semiconductor nanoparticle complex cured membrane according to claim 1, wherein
when the semiconductor nanoparticle complex cured membrane is formed to have a thickness of 10 μm, an absorbance of the semiconductor nanoparticle complex cured membrane with respect to light having a wavelength of 450 nm from the normal direction of the membrane is 1.0 or more.

5. The semiconductor nanoparticle complex cured membrane according to claim 1, wherein
when the semiconductor nanoparticle complex cured membrane is formed to have a thickness of 10 μm, an absorbance of the semiconductor nanoparticle complex cured membrane with respect to light having a wavelength of 450 nm from the normal direction of the membrane is 1.5 or more.

6. The semiconductor nanoparticle complex cured membrane according to claim 1, wherein the scattering agent is a metal oxide.

7. The semiconductor nanoparticle complex cured membrane according to claim 1, wherein a fluorescence quantum yield of the semiconductor nanoparticle complex cured membrane is 70% or more.

8. The semiconductor nanoparticle complex cured membrane according to claim 1, wherein the mass ratio of the ligand to the semiconductor nanoparticle (ligand/semiconductor nanoparticle) is 0.05 to 0.50.

9. The semiconductor nanoparticle complex cured membrane according to claim 1, wherein the ligand has one or more mercapto groups.

10. The semiconductor nanoparticle complex cured membrane according to claim 9, wherein the ligand has two or more mercapto groups.

11. The semiconductor nanoparticle complex cured membrane according to claim 1, wherein there are two or more types of ligands.

12. The semiconductor nanoparticle complex cured membrane according to claim 1, wherein the semiconductor nanoparticle includes In and P.

13. The semiconductor nanoparticle complex cured membrane according to claim 1, wherein Zn is contained on the surface of the semiconductor nanoparticle.

14. The semiconductor nanoparticle complex cured membrane according to claim 1, wherein the thickness of the semiconductor nanoparticle complex cured membrane is 50 μm or less.
